(19) United States
(12) Patent Application Publication
(10) Pub. No.: US 2009/0151998 A1
(43) Pub. Date: Jun. 18, 2009

(54) ELECTROMAGNETIC WAVE SHIELDING WIRING CIRCUIT FORMING METHOD AND ELECTROMAGNETIC WAVE SHIELDING SHEET

(75) Inventors: Hidemichi Fujiwara, Tokyo (JP); Shunji Masumori, Tokyo (JP); Yusuke Yamada, Tokyo (JP); Hideo Nishikubo, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: THE FURUKAWA ELECTRIC CO., LTD., Tokyo (JP)

(21) Appl. No.: 12/265,004

(22) Filed: Nov. 5, 2008

(30) Foreign Application Priority Data
Nov. 6, 2007 (JP) 2007-288121
Nov. 4, 2008 (JP) 2008-282791

(51) Int. Cl. H05K 9/00; H05K 3/12

(52) U.S. Cl. 174/350; 427/98.4; 427/97.4

(57) ABSTRACT

The electromagnetic wave shielding wiring circuit forming method of the present invention comprises the steps of: preparing a fine copper particle dispersion, by dispersing fine copper particles into a disperse medium (S) including an organic solvent (A) having an amide-based compound, an organic solvent (B) having a boiling point of 20° C. or higher at an ordinary pressure and having a donor number of 17 or more, an organic solvent (C) having a boiling point exceeding 100° C. at an ordinary pressure and comprising alcohol and/or polyhydric alcohol, and an organic solvent (E) having an amine-based compound, at specific ratios; coating or printing the fine copper particle dispersion onto a substrate, to form a wiring pattern comprising a liquid film of the fine copper particle dispersion; and firing the liquid film of the fine copper particle dispersion, to form a sintered wiring layer.

### BACKGROUND OF THE INVENTION

1. Field of the Invention

The present invention relates to an electromagnetic wave shielding wiring circuit forming method using a fine copper particle dispersion, and to an electromagnetic wave shielding sheet.

2. Related Arts

As compared with cathode ray tubes, liquid crystal displays, and the like, plasma display panels (hereinafter abbreviated to “PDP”) each emit a large amount of electromagnetic waves from a panel front surface upon light emission, thereby requiring an electromagnetic wave shielding filter to be mounted on the panel surface.

Known as conventional electromagnetic wave shielding filters, are those comprising plastic substrates having surfaces formed with metal thin-films in meshed wiring patterns, respectively. From a standpoint to prevent reflection of outside light and to be free of influence on color tones of displays, the wirings of such electromagnetic wave shielding filters desirably comprise: metal lines colored in substantially black in themselves, respectively; metal lines having black colored surfaces, respectively; or metal lines having black color layers on surfaces thereof, respectively.

As a method for forming a meshed wiring pattern, there has been utilized a photolithography technique for performing a series of processes including: formation of a metal film such as by adherence of a copper foil onto a substrate, or by silver sputtering; resist coating; exposure; development; etching; and the like. However, this method requires the considerably increased number of processes, thereby problematically increasing a production cost.

As such, JP-2006-169592A has proposed a method comprising the steps of: printing a fine metal particle dispersion containing fine metal particles having an averaged particle diameter 100 nm or less and black-colored inorganic fine particles having an averaged particle diameter of 300 nm or less, onto a substrate by inkjetting or the like; and subsequently forming wirings, by heat treatment, or by seizure based on laser irradiation; and has described that such a wiring forming method is to be utilized for formation of wirings of address electrodes, bus electrodes in PDP, liquid crystal display panels, and the like.

However, the above-described fine metal particle dispersion is susceptible to agglomeration of fine metal particles in the disperse medium to exhibit a deteriorated dispersibility of fine particles, thereby resulting in a problem of deteriorated storage stability and delivery stability upon usage of the dispersion as an inkjetting ink. There can be then conceived a method for protecting surfaces of fine metal particles by a dispersant. However, since fine metal particles are dispersed together with inorganic fine particles acting as pigments, the dispersant for fine metal particles preferentially coordinates with inorganic fine particles depending on the kind of the inorganic fine particles to be blended and thus the dispersant does not act correctly, thereby possibly resulting in occurrence of a considerably deteriorated delivery stability due to coarse complex particles made of fine metal particles and inorganic fine particles.

Against such a problem, there have been proposed various dispersions comprising disperse media and fine metal particles dispersed therein and having surfaces coated with polymeric compounds, respectively, as fine metal particle dispersions exhibiting improved dispersibility and delivery stability. For example, JP-2002-299833A has proposed to form a circuit pattern, by utilizing a fine metal particle dispersion comprising an organic solvent, and metal nano particles stably dispersed therein and having surfaces coated with organic compounds.

In this respect, as fine metal particles to be used as PDP-oriented electromagnetic wave shielding wiring circuits, it is desirable to adopt copper ones from a standpoint that metal copper materials are remarkably inexpensive as compared with gold, silver, nickel, and the like, and a standpoint to avoid short circuits among wirings due to electromigration to be otherwise caused upon usage of silver.

However, in using a dispersion of fine particles of copper, copper alloy, or copper compound (hereinafter simply called “fine copper particles”), heating thereof in an oxidative atmosphere results in oxidation of copper and thus in a lowered electrical conductivity, so that the fine copper particles are required to be heated in an inert gas atmosphere or a reducing gas atmosphere such as hydrogen gas atmosphere. Thus, in such a case that fine copper particles have surfaces coated with thick polymeric compound layers, the polymers having higher heat resistance are scarcely decomposed in an inert gas or reducing gas atmosphere containing no oxygen, in a manner to obstruct sintering among fine copper particles, thereby resulting in an insufficient electrical conductivity of sintered wirings to be eventually obtained.

Although it is conceivable to conduct firing at a high-temperature to sublimate polymeric compounds so as to obtain an improved electrical conductivity, conduction of firing at such a high-temperature leads to failure of usage of a plastic substrate having a lower heat-resistance temperature as a substrate to be coated with a dispersion, thereby problematically resulting in difficulty in application to PDP-oriented electromagnetic wave shielding wiring circuits.

Although the aforementioned JP-2002-299833A has described that circuit patterns can be formed at firing temperatures at 250° C. or lower in case of adoption of silver as metal nano particles, no consideration is provided for a problem in case of adopting copper as metal nano particles. Namely, unlike a case of adoption of silver substantially insusceptible to oxidation, it is not considered therein that adoption of fine copper particles requires heating thereof in an inert gas atmosphere or a reducing gas atmosphere such as hydrogen gas such that polymers which cover the fine copper particles are scarcely decomposed insofar as by low-temperature sintering and thus the sintered wirings are made insufficient in electrical conductivity, thereby disabling application to a plastic substrate having a lower heat-resistance temperature.

### BRIEF SUMMARY OF THE INVENTION

It is therefore an object of the present invention to provide: an electromagnetic wave shielding wiring circuit forming method, capable of realizing one by adopting copper which is inexpensive and free of occurrence of electromigration; and an electromagnetic wave shielding sheet.

The present invention provides a first configuration residing in an electromagnetic wave shielding wiring circuit forming method comprising the steps of:

preparing a fine copper particle dispersion, by dispersing fine copper particles (P) into a disperse medium (s) selected from:
(i) a disperse medium (S1) including an organic solvent (A) having an amide-based compound, an organic solvent (B) having a boiling point of 20° C. or higher at an ordinary pressure and having a donor number of 17 or more as an electron donating ability, and an organic solvent (C) having a boiling point exceeding 100° C. at an ordinary pressure and comprising alcohol and/or polyhydric alcohol;
(ii) a disperse medium (S2) including an organic solvent (A) having an amide-based compound, and an organic solvent (C) having a boiling point exceeding 100° C. at an ordinary pressure and comprising alcohol and/or polyhydric alcohol;
(iii) a disperse medium (S3) including organic solvent (C) having a boiling point exceeding 100° C. at an ordinary pressure and comprising alcohol and/or polyhydric alcohol;
(iv) a disperse medium (S4) including 24 to 64 vol % of an organic solvent (A) having an amide-based compound, 5 to 39 vol % of a low-boiling organic solvent (B) having a boiling point between 20° C. and 100° C. at an ordinary pressure, 30 to 70 vol % of an organic solvent (C) having a boiling point exceeding 100° C. at an ordinary pressure and comprising alcohol and/or polyhydric alcohol, and 1 to 40 vol % of an organic solvent (E) having an amine-based compound;
(v) a disperse medium (S5) including 30 to 94 vol % of an organic solvent (A) having an amide-based compound, 30 to 94 vol % of an organic solvent (C) having a boiling point exceeding 100° C. at an ordinary pressure and comprising alcohol and/or polyhydric alcohol, and 1 to 40 vol % of an organic solvent (E) having an amine-based compound; and
(vi) a disperse medium (S6) including 60 to 99 vol % of an organic solvent (C) having a boiling point exceeding 100° C. at an ordinary pressure and comprising alcohol and/or polyhydric alcohol, and 1 to 40 vol % of an organic solvent (E) having an amine-based compound;

coating or printing the fine copper particle dispersion onto a substrate or a black-colored layer formed on the substrate, to form a wiring pattern comprising a liquid film of the fine copper particle dispersion; and

firing the liquid film of the fine copper particle dispersion, to form a sintered wiring layer.

Note that the donor number is defined as a formation enthalpy ΔH (kcal/mol) to be measured for formation equilibrium of a 1:1 complex of SbCl₅ and a (electron donating) solvent molecule in 1,2-dichloroethane, in calorimetry.

The present invention provides a second configuration residing in the electromagnetic wave shielding wiring circuit forming method of the first configuration, further comprising the step of: forming a black-colored layer on the sintered wiring layer.

The present invention provides a third configuration residing in the electromagnetic wave shielding wiring circuit forming method of the second configuration, wherein the black-colored layer is formed by coating or printing a pigment dispersion including a black-colored inorganic pigment overlappingly onto the substrate or the sintered wiring layer.

The present invention provides a fourth configuration residing in the electromagnetic wave shielding wiring circuit forming method of any one of the first through third configurations, wherein the coating or printing is conducted by an inkjetting or screen printing method, respectively.

The present invention provides a fifth configuration residing in an electromagnetic wave shielding wiring circuit forming method comprising the steps of:

preparing a fine copper particle dispersion, by dispersing fine copper particles (P) into a disperse medium (s) selected from:
(i) a disperse medium (S1) including an organic solvent (A) having an amide-based compound, an organic solvent (B) having a boiling point of 20° C. or higher at an ordinary pressure and having a donor number of 17 or more as an electron donating ability, and an organic solvent (C) having a boiling point exceeding 100° C. at an ordinary pressure and comprising alcohol and/or polyhydric alcohol;
(ii) a disperse medium (S2) including an organic solvent (A) having an amide-based compound, and an organic solvent (C) having a boiling point exceeding 100° C. at an ordinary pressure and comprising alcohol and/or polyhydric alcohol;

(iii) a disperse medium (S3) including organic solvent (C) having a boiling point exceeding 100° C. at an ordinary pressure and comprising alcohol and/or polyhydric alcohol;
(iv) a disperse medium (S4) including 24 to 64 vol % of an organic solvent (A) having an amide-based compound, 5 to 39 vol % of a low-boiling organic solvent (B) having a boiling point between 20° C. and 100° C. at an ordinary pressure, 30 to 70 vol % of an organic solvent (C) having a boiling point exceeding 100° C. at an ordinary pressure and comprising alcohol and/or polyhydric alcohol, and 1 to 40 vol % of an organic solvent (E) having an amine-based compound;
(v) a disperse medium (S5) including 30 to 94 vol % of an organic solvent (A) having an amide-based compound, 30 to 94 vol % of an organic solvent (C) having a boiling point exceeding 100° C. at an ordinary pressure and comprising alcohol and/or polyhydric alcohol, and 1 to 40 vol % of an organic solvent (E) having an amine-based compound; and
(vi) a disperse medium (S6) including 60 to 99 vol % of an organic solvent (C) having a boiling point exceeding 100° C. at an ordinary pressure and comprising alcohol and/or polyhydric alcohol, and 1 to 40 vol % of an organic solvent (E) having an amine-based compound;

(a) coating or printing the fine copper particle dispersion onto a substrate, to form a wiring pattern comprising a liquid film of the fine copper particle dispersion;

(b) coating or printing a pigment dispersion including a black-colored inorganic pigment, overlappingly onto the liquid film of the fine copper particle dispersion; and

firing the liquid film of the fine copper particle dispersion and the pigment dispersion, to form a sintered wiring having a two-layer structure comprising a sintered copper layer and a black-colored layer.

The present invention provides a sixth configuration residing in the electromagnetic wave shielding wiring circuit forming method of the fifth configuration, wherein the step (b) is conducted after the step (a).

The present invention provides a seventh configuration residing in the electromagnetic wave shielding wiring circuit forming method of the fifth or sixth configuration, wherein the coating or printing is conducted by an inkjetting or screen printing method, respectively.

The present invention provides an eighth configuration residing in an electromagnetic wave shielding sheet comprising:

a wiring circuit formed by the electromagnetic wave shielding wiring circuit forming method of any one of the first to seventh configurations; and

protective films provided on both upper and lower surfaces of the wiring circuit, respectively.

### BRIEF DESCRIPTION OF THE DRAWINGS

FIG. 1 is a cross-sectional view of an embodiment of an electromagnetic wave shielding sheet having an electromagnetic wave shielding wiring circuit of the present invention; and

FIG. 2 is a cross-sectional view of an embodiment of an electromagnetic wave shielding panel having an electromagnetic wave shielding wiring circuit of the present invention.

### DETAILED DESCRIPTION OF THE INVENTION

### First Embodiment

The electromagnetic wave shielding wiring circuit forming method according to a first embodiment of the present invention includes, as indispensable steps, the steps of:

preparing a fine copper particle dispersion, by dispersing fine copper particles into a disperse medium (S) selected from:
(i) a disperse medium (S1) including an organic solvent (A) having an amide-based compound, an organic solvent (B) having a boiling point of 20° C. or higher at an ordinary pressure and having a donor number of 17 or more, and an organic solvent (C) having a boiling point exceeding 100° C. at an ordinary pressure and comprising alcohol and/or polyhydric alcohol having one or two or more hydroxyl groups in each molecule;
(ii) a disperse medium (S2) including an organic solvent (A) having an amide-based compound, and an organic solvent (C) having a boiling point exceeding 100° C. at an ordinary pressure and comprising alcohol and/or polyhydric alcohol having one or two or more hydroxyl groups in each molecule;
(iii) a disperse medium (S3) including organic solvent (C) having a boiling point exceeding 100° C. at an ordinary pressure and comprising alcohol and/or polyhydric alcohol having one or two or more hydroxyl groups in each molecule;
(iv) a disperse medium (S4) including 24 to 64 vol % of an organic solvent (A) having an amide-based compound, 5 to 39 vol % of a low-boiling organic solvent (B) having a boiling point between 20° C. and 100° C. at an ordinary pressure, 30 to 70 vol % of an organic solvent (C) having a boiling point exceeding 100° C. at an ordinary pressure and comprising alcohol and/or polyhydric alcohol having one or two or more hydroxyl groups, and 1 to 40 vol % of an organic solvent (E) having an amine-based compound;
(v) a disperse medium (S5) including 30 to 94 vol % of an organic solvent (A) having an amide-based compound, 30 to 94 vol % of an organic solvent (C) having a boiling point exceeding 100° C. at an ordinary pressure and comprising alcohol and/or polyhydric alcohol, and 1 to 40 vol % of an organic solvent (E) having an amine-based compound; and
(vi) a disperse medium (S6) including 60 to 99 vol % of an organic solvent (C) having a boiling point exceeding 100° C. at an ordinary pressure and comprising alcohol and/or polyhydric alcohol, and 1 to 40 vol % of an organic solvent (E) having an amine-based compound;

coating or printing the fine copper particle dispersion onto a substrate or a black-colored layer formed on the substrate, to form a wiring pattern comprising a liquid film of the fine copper particle dispersion; and

firing the liquid film of the fine copper particle dispersion, to form a sintered wiring layer; and

the forming method includes, as required, a step of forming a black-colored layer on the substrate or the sintered wiring layer.

The electromagnetic wave shielding wiring circuit forming method according to the first embodiment of the present invention will be explained hereinafter.

(Fine Copper Particle Dispersion)

There will be firstly explained constituent components of a fine copper particle dispersion of the present invention.

Fine Copper Particle:

The fine copper particle of the present invention embraces fine particles of copper, copper alloy, and copper compound, and the copper compound embraces oxides of copper and copper alloy. Fine copper particles which are transition metal particles are scarcely free of oxides, and oxidation levels in such cases are varied depending on atmospheres, temperatures, and retention times during production and storage of the fine particles, such that fine particles are thinly oxidized only at outermost surfaces thereof while interiors thereof are kept unchanged in some cases, and fine particles are mostly oxidized in some cases. The term “copper compound” used in the present invention fully embraces those particles in such various oxidation states.

Organic Solvent (A):

The organic solvent (A) is an amide-based compound having an amide group (—CONH—) or an organic solvent containing an amide-based compound, and has a function to improve a dispersibility and a storage stability of fine particles in an applicable disperse medium, and to improve an adherence of a sintered wiring layer to a substrate when the disperse medium in a state containing fine copper particles is fired on the substrate.

Particularly desirable are those amide-based compounds having higher specific dielectric constants, respectively. Examples of amide-based compounds include N-methylacetamide (191.3 at 32° C.), N-methylformamide (182.4 at 20° C.), N-methylpropaneamide (172.2 at 25° C.), formamide (111.0 at 20° C.), N,N-dimethylacetamide (37.78 at 25° C.), 1,3-dimethyl-2-imidazolidinone (37.6 at 25° C.), N,N-dimethylformamide (36.7 at 25° C.), 1-methyl-2-pyrrolidone (32.58 at 25° C.), hexamethyl phosphoric triamide (29.0 at 0° C.), 2-pyrrolidinone, ∈-caprolactam, acetamide, and the like, and these may be mixedly used. Note that the numerical values in the parentheses after the amide-based compound names indicate specific dielectric constants at measuring temperatures of the solvents, respectively. Preferably usable among them are N-methylacetamide, N-methylformamide, formamide, acetamide, and the like having specific dielectric constants of 100 or higher, respectively. Note that if the applicable amide-based compound such as N-methylacetamide (melting point: 26 to 28° C.) is solid at an ordinary temperature, it can be used in a liquid state at a working temperature by mixing it with another solvent.

Organic Solvent (B):

The organic solvent (B) is an organic compound having a boiling point of 20° C. or higher at an ordinary pressure and having a donor number of 17 or more. Boiling points below 20° C. at an ordinary pressure possibly result in that the component of the organic solvent (B) is easily volatilized when a fine particle dispersion including the organic solvent (B) is stored at an ordinary temperature, thereby changing the solvent composition of the dispersion. Further, the lower boiling point of the solvent at an ordinary pressure allows for expectation that mutual attractive forces among molecules of solvents are lowered by virtue of addition of this solvent, such that the effect of this solvent to further improve the dispersibility of fine particles is effectively exhibited. Donor numbers less than 17 result in an electron-pair donating ability lower than that of water, such that an influence of interaction between copper particles and water is enhanced upon mixture of water as impurity, thereby undesirably causing oxidation of the particles.

Note that boiling points of 200° C. or lower at an ordinary pressure allows for expectation that mutual attractive forces among molecules of solvents are lowered by virtue of addition of this solvent, such that the effect of this solvent to further improve the dispersibility of fine particles is effectively exhibited.

Further, higher electron donating abilities have an effect to donate electrons to copper particles and molecules coordinated therearound to enhance negative electrostatic properties of the copper particles, thereby increasing electrostatic repulsive forces among the particles. Particularly desirable among the organic solvents (B) is an ether-based compound (B1), because the same is well balanced between a boiling point and a donor number, and the same functions to lower interactions between molecules of solvents and to exhibit an enhanced electron donation effect.

Furthermore, adoption of the organic solvent (B) remarkably shortens a stirring time upon preparation of a fine particle dispersion such as by irradiation of ultrasonic waves, down to about ½, for example. Moreover, presence of the organic solvent (B) in the mixed organic solvent enables easier re-dispersion even when fine particles have been once brought into agglomerated states.

Examples of the organic solvent (B) include: an ether-based compound (B1) represented by a general formula of R1—O—R2 (R1 and R2 are independently alkyl groups, respectively, and each have a carbon atom number of 1 to 4); an alcohol (B2) represented by a general formula of R3 —OH(R3 is an alkyl group having a carbon atom number of 1 to 4); a ketone-based compound (B3) represented by a general formula R4—C(═O)—R5 (R4 and R5 are independently alkyl groups, respectively, and each have a carbon atom number of 1 to 2); and an amine-based compound (B4) represented by a general formula of R6—(N—R7)—R8 (R6, R7, and R8 are independently alkyl groups or a hydrogen atom, respectively, and each have a carbon atom number of 0 to 2). The examples of the organic solvents (B) will be described hereinafter, and numerical values in the parentheses after compound names indicate boiling points of the compounds at an ordinary pressure, respectively.

Examples of the ether-based compound (B1) include diethyl ether (35° C.), methylpropyl ether (31° C.), dipropyl ether (89° C.), diisopropyl ether (68° C.), methyl-t-butyl ether (55.3° C.), t-amylmethyl ether (85° C.), divinyl ether (28.5° C.), ethylvinyl ether (36° C.), allyl ether (94° C.), and the like.

Examples of the alcohol (B2) include methanol (64.7° C.), ethanol (78.0° C.), 1-propanol (97.15° C.), 2-propanol (82.4° C.), 2-butanol (100° C.), 2-methyl-2-propanol (83° C.), and the like.

Examples of the ketone-based compound (B3) include acetone (56.5° C.), methyl ethyl ketone (79.5° C.), diethyl ketone (100° C.), and the like.

Examples of the amine-based compound (B4) include triethylamine (89.7° C.), diethylamine (55.5° C.), and the like.

Organic Solvent (C):

The organic solvent (C) is an organic compound having a boiling point exceeding 100° C. at an ordinary pressure and comprising alcohol and/or polyhydric alcohol having one or two or more hydroxyl groups in each molecule, and both the alcohol and polyhydric alcohol have boiling points above 100° C. at an ordinary pressure in this case. Desirable are: alcohols each having a carbon number of 5 or more and polyhydric alcohols each having a carbon number of 2 or more; and those which are liquid at an ordinary temperature and have higher specific dielectric constants such as 10 or more.

Although the mixed organic solvent containing the organic solvent (A) and organic solvent (B) exhibits an improved dispersibility by stirring, fine particles in an organic solvent typically tend to agglutinate after a lapse of time. Presence of the organic solvent (C) in an applicable mixed organic solvent enables to more effectively restrict such agglutination, thereby improving dispersibility of fine copper particles and achieving long-term stability of the dispersion, to thereby improve uniformity of an eventually obtained sintered wiring. Further, the organic solvent (C) generates a reducing substance upon thermal decomposition to allow for reduction of oxidized coats of fine copper particles, thereby providing an advantage that a reducing gas atmosphere is not required in a firing step to be described later.

Concrete examples of the organic solvent (C) include ethylene glycol, diethylene glycol, 1,2-propanediol, 1,3-propanediol, 1,2-butanediol, 1,3-butanediol, 1,4-butanediol, 2-butene-1,4-diol, 2,3-butanediol, pentanediol, hexanediol, octanediol, glycerol, 1,1,1-tris(hydroxymethyl)ethane, 2-ethyl-2-hydroxymethyl-1,3-propanediol, 1,2,6-hexanetriol, 1,2,3-hexanetriol, 1,2,4-butanetriol, and the like.

Further usable are sugar alcohols such as D-threitol, erythritol, pentaerythritol, pentitol, hexitol, or the like. Examples of pentitol include xyltol, ribitol, and arabitol. The hexitol embraces mannitol, sorbitol, dulcitol, and the like. Further usable are saccharides such as glyceric aldehyde, dioxy-acetone, threose, erythrulose, erythrose, arabinose, ribose, ribulose, xylose, xylulose, lyxose, glucose, fructose, mannose, idose, sorbose, gulose, talose, tagatose, galactose, allose, altrose, lactose, xylose, arabinose, isomaltose, gluco-heptose, heptose, maltotriose, lactulose, and trehalose.

Among the above alcohols, those polyhydric alcohols having two or more hydroxyl groups in each molecule are preferable, and ethylene glycol and glycerin are particularly preferable.

Organic Solvent (E):

The organic solvent (E) has a boiling point of 20° C. or higher at an ordinary pressure. This is: one kind or two or more kinds of amine-based compounds selected from aliphatic primary amines, aliphatic secondary amines, aliphatic tertiary amines, aliphatic unsaturated amines, alicyclic amines, aromatic amines, and alkanol amines; or an organic solvent including these amine-based compounds.

Examples of the amine-based compounds include methylamine, dimethylamine, trimethylamine, ethylamine, diethylamine, triethylamine, n-propylamine, n-butylamine, t-propylamine, t-butylamine, ethylenediamine, propylenediamine, tetramethylenediamine, tetramethylpropylenediamine, pentamethyldiethylenetriamine, mono-n-octylamine, mono-2-ethylhexylamine, di-n-octylamine, di-2-ethylhexylamine, tri-n-octylamine, tri-2-ethylhexylamine, triisobutylamine, trihexylamine, triisooctylamine, triisononylamine, triphenylamine, dimethylcoconutamine, dimethyloctylamine, dimethyldecylamine, dimethyllaurylamine, dimethylmyristylamine, dimethylpalmitylamine, dimethylstearylamine, dimethylbehenylamine, dilaurylmonomethylamine, diisopropylethylamine, methanolamine, dimethanolamine, trimethanolamine, ethanolamine, diethanolamine, triethanolamine, propanolamine, isopropanolamine, diisopropanolamine, triisopropanolamine, butanolamine, N-methylethanolamine, N-methyldiethanolamine, N,N-dimethylethanolamine, N-ethylethanolamine, N-ethyldiethanolamine, N,N-diethylethanolamine, N-n-butylethanolamine, N-n-butyldiethanolamine, and 2-(2-aminoethoxy)ethanol.

When the applicable amine-based compound is gas or solid at an ordinary temperature, it can be dissolved in another solvent and used as a liquid solution at a working temperature.

Disperse Medium (S):

The disperse medium (S) is selected from among the following disperse media (S1) to (S6).

Disperse Medium (S1):

The disperse medium (S1) is a mixed organic solvent including the organic solvent (A), the organic solvent (B), and the organic solvent (C). Blending amounts of the organic solvents in the disperse medium (S1) are preferably 5 to 90 vol % for the organic solvent (A), 5 to 45 vol % for the organic solvent (B), and 5 to 90 vol % for the organic solvent (C).

The organic solvent (A), organic solvent (B), and organic solvent (C) may be blended at the above blending ratios in a manner to attain 100 vol %, or it is possible to additionally blend another organic solvent component within the above blending ratios to an extent not to deteriorate the effect of the present invention, and in the latter case, it is preferable that the components comprising the organic solvent (A), organic solvent (B), and organic solvent (C) are totally included in an amount of 90 vol % or more, and more preferably 95 vol % or more.

In case of blending an organic solvent component(s) other than the above-described ones, it is desirable to use a polar organic solvent such as tetrahydrofuran, diglyme, ethylene carbonate, propylene carbonate, sulfolane, or dimethyl sulfoxide.

By dispersing fine copper particles in the disperse medium (S1) including such specific organic solvent (A), organic solvent (B), and organic solvent (C), it becomes possible to improve dispersibility of the fine particles, for: those fine copper particles which are substantially free of presence of polymeric compounds at surfaces of the fine particles; or even those fine copper particles having a polymeric dispersant (D) attached to surfaces of the fine particles such that the weight ratio (D/P) between the polymeric dispersant (D) and fine copper particle (P) is in a range of 0<D/P<0.01. In this way, by using a dispersion of: those fine copper particles which are substantially free of presence of polymeric compounds at surfaces of the fine particles; or those fine copper particles having a small amount of polymeric dispersant attached to surfaces of the fine particles; it becomes possible to eliminate or mitigate the factor which obstructs sintering among fine copper particles themselves, thereby enabling low-temperature firing in the firing step to be described later. Further, by coating the fine copper particle dispersion adopting the disperse medium (S1) onto a coating target followed by firing, it becomes possible to obtain a sintered body having a higher electrical conductivity and an improved adherence to the coating target, even by low-temperature firing.

To effectively attain such features, the blending amount of the organic solvent (A) in the disperse medium (S1) is preferably 50 to 90 vol %, and more preferably 60 to 80 vol %. The blending amount of the organic solvent (B) is preferably 5 to 40 vol %, and more preferably 10 to 30 vol %, and the blending amount of the organic solvent (C) is preferably 5 to 45 vol %, and more preferably 10 to 30 vol %.

Disperse Medium (S2):

The disperse medium (S2) is a mixed organic solvent including the organic solvent (A) and the organic solvent (C). Blending amounts of the organic solvents in the disperse medium (S2) are preferably 5 to 95 vol % for the organic solvent (A), and 5 to 95 vol % for the organic solvent (C).

The organic solvent (A) and organic solvent (C) may be blended at the above blending ratios in the disperse medium (S2) in a manner to attain 100 vol %, or it is possible to additionally blend another organic solvent component within the above blending ratios to an extent not to deteriorate the effect of the present invention. In the latter case, it is preferable that the components comprising the organic solvent (A) and organic solvent (C) are totally included in an amount of 90 vol % or more, and more preferably 95 vol % or more.

In case of blending an organic solvent component(s) other than the above-described ones, it is possible to use a polar organic solvent such as tetrahydrofuran, diglyme, ethylene carbonate, propylene carbonate, sulfolane, or dimethyl sulfoxide.

By dispersing fine copper particles in the disperse medium (S2) including such specific organic solvent (A) and organic solvent (C), it becomes possible to improve dispersibility of the fine particles, and to enable low-temperature firing in the firing step to be described later, similarly to the disperse medium (S1). Further, it becomes possible to obtain a sintered body having a higher electrical conductivity and an improved adherence to the coating target, even by low-temperature firing.

To effectively attain such features, the blending amount of the organic solvent (A) in the disperse medium (S2) is preferably 50 to 90 vol %, and more preferably 60 to 80 vol %. Further, the blending amount of the organic solvent (C) is preferably 10 to 50 vol %, and more preferably 20 to 40 vol %.

Disperse Medium (S3):

The disperse medium (S3) is an organic solvent including the organic solvent (C). As compared with the disperse medium (S1) and disperse medium (S2), this disperse medium (S3) is slightly inferior in dispersibility, but enables low-temperature firing in the firing step to be described later, thereby enabling obtainment of a sintered body having a higher electrical conductivity even by low-temperature firing.

Disperse Medium (S4):

The disperse medium (S4) is a mixed organic solvent including 24 to 64 vol % of the organic solvent (A), 5 to 39 vol % of the organic solvent (B), 30 to 70 vol % of the organic solvent (C), and 1 to 40 vol % of the organic solvent (E).

The organic solvent (A), organic solvent (B), organic solvent (C), and organic solvent (E) may be blended at the above blending ratios in a manner to attain 100 vol %, or it is possible to additionally blend another organic solvent component within the above blending ratios to an extent not to deteriorate the effect of the present invention. In the latter case, it is preferable that the components comprising the organic solvent (A), organic solvent (B), organic solvent (C), and organic solvent (E) are totally included in an amount of 90 vol % or more, and more preferably 95 vol % or more.

In case of blending an organic solvent component(s) other than the above-described ones, it is desirable to use a polar organic solvent such as tetrahydrofuran, diglyme, ethylene carbonate, propylene carbonate, sulfolane, or dimethyl sulfoxide.

Disperse Medium (S5):

The disperse medium (S5) is a mixed organic solvent of 30 to 94 vol % of the organic solvent (A), 30 to 94 vol % of the organic solvent (C), and 1 to 40 vol % of the organic solvent (E). Amounts of the organic solvent (A) less than 30 vol % might lead to insufficient dispersibility and storage stability of fine particles (P) of metal or the like in a polar organic solvent.

The organic solvent (C) is required to be included in the disperse medium (S5), in an amount of 30 vol % or more. Such a blending ratio of the organic solvent (C) restricts agglomeration of fine copper particles (P) in the disperse medium (S5) even after a long-term storage to thereby further improve a dispersion stability, and improves denseness and electrical conductivity of a fired film to be obtained by firing the fine particle dispersion.

The organic solvent (E) is required to be included in the disperse medium (S5), in an amount of 1 to 40 vol %. Such a blending ratio of the organic solvent (E) causes dispersed particles to have an improved affinity to the solvent in the disperse medium (S5), thereby restricting agglomeration of fine copper particles (P) even after a long-term storage, to thereby further improve a dispersion stability.

Note that, since the organic solvent (C) and organic solvent (E) are made coexistent in the disperse medium (S5), parts of the organic solvent (C) and organic solvent (E) are considered to be existent in a manner to cover surfaces of fine copper particles (P) in the disperse medium (S5). Thus, in order for the organic solvent (C) in the disperse medium (S5) to exhibit its function to further improve denseness and electrical conductivity of a fired film to be obtained by firing the fine particle dispersion, the organic solvent (C) is required to be blended in an amount of 30 vol % or more, so that the organic solvent (A) is required to be included in an amount of 30 to 94 vol % so as to exhibit the aforementioned effect thereof.

The organic solvent (A), organic solvent (C), and organic solvent (E) may be blended at the above blending ratios in a manner to attain 100 vol %, or it is possible to additionally blend another organic solvent component within the above blending ratios to an extent not to deteriorate the effect of the present invention. In the latter case, it is preferable that the components comprising the organic solvent (A), organic solvent (C), and organic solvent (E) are totally included in an amount of 90 vol % or more, and more preferably 95 vol % or more.

In case of blending an organic solvent component(s) other than the above-described ones, it is desirable to use a polar organic solvent such as tetrahydrofuran, diglyme, ethylene carbonate, propylene carbonate, sulfolane, or dimethyl sulfoxide.

Disperse Medium (S6):

The disperse medium (S6) is a mixed organic solvent of 60 to 99 vol % of the organic solvent (C), and 1 to 40 vol % of the organic solvent (E).

The organic solvent (C) and organic solvent (E) (D) may be blended at the above blending ratios in a manner to attain 100 vol %, or it is possible to additionally blend another organic solvent component within the above blending ratios to an extent not to deteriorate the effect of the present invention. In the latter case, it is preferable that the components comprising the organic solvent (C) and organic solvent (E) are totally included in an amount of 90 vol % or more, and more preferably 95 vol % or more.

The organic solvent (C) is required to be included in the disperse medium (S6), in an amount of 60 vol % or more. Such a blending ratio of the organic solvent (C) restricts agglomeration of fine copper particles (P) in the disperse medium (S6) even after a long-term storage to thereby further improve a dispersion stability, and improves denseness and electrical conductivity of a fired film to be obtained by firing the fine particle dispersion.

The organic solvent (E) is required to be included in the disperse medium (S6), in an amount of 1 to 40 vol %. Such a blending ratio of the organic solvent (D) causes dispersed particles to have an improved affinity to the solvent in the disperse medium (S6), thereby restricting agglomeration of fine copper particles (P) even after a long-term storage, to thereby further improve a dispersion stability.

The disperse media (S1) to (S6) each include the organic solvent (C) to thereby produce a reducing substance upon thermal decomposition in a manner to allow for reduction of oxidized coats of fine copper particles, thereby exhibiting an effect to eliminate necessity of a reducing gas atmosphere in a firing step. Further, when the fine copper particle dispersion including the organic solvent (C) is coated onto a coating target and then fired, the higher dispersing ability and reduction promoting ability possessed by the organic solvent (C) allow for improvement of a uniformity and electrical conductivity of a sintered body.

Further, although the applicable mixed organic solvent including the organic solvent (A) and organic solvent (B) exhibits an improved dispersibility by stirring, fine particles in an organic solvent typically tend to agglutinate after a lapse of time. Presence of the organic solvent (C) in the applicable disperse medium enables to more effectively restrict such agglutination, thereby improving dispersibility of fine copper particles and achieving long-term stability of the dispersion.

In case of the disperse media (S1) and (S2) to be used in the present invention, it is more preferable that the concentration of the organic solvent (C) is practically set at about 20 to 90 vol %. In case of the disperse media (S4) and (S5), the organic solvent (C) is required to be blended in an amount of 30 to 60 vol % or more so as to allow the organic solvent (A) and organic solvent (E) to coexist, and to further improve denseness and electrical conductivity of an obtained fired film. Further, in case of the disperse medium (S6), it is more preferable that the concentration of the organic solvent (C) is practically set at about 70 to 90 vol % based on coexistence with the organic solvent (E).

(Preparing Step of Fine Copper Particle Dispersion)

There will be explained a preparing step of a fine copper particle dispersion.

The fine copper particle dispersion is prepared by dispersing fine copper particles into a disperse medium selected from the disperse media (S1) to (S6).

Concretely, it is possible to prepare a fine copper particle dispersion, by removing impurities including a polymeric dispersant (D) from fine copper particles (Pc) such as obtained by a liquid phase reductive reaction or a known reductive reaction for copper-ion in a water solution in the presence of the polymeric dispersant (D), and by re-dispersing fine copper particles (P) having surfaces free of coating of the polymeric dispersant (D) or having surfaces coated with a relatively small amount of the polymeric dispersant (D), into the disperse medium (S).

Usable for formation of copper ions are copper chloride, copper nitrate, copper nitrite, copper sulfate, copper acetate, and the like.

As a method for removing the polymeric dispersant (D), it is possible to adopt a method to add an agglomeration promoter into the water solution after completion of the reductive reaction to thereby agglomerate or precipitate fine copper particles, followed by separation of the agglomerated or precipitated fine particles from the water solution by a filtering operation, for example.

Although it is possible to adopt a known stirring method as a method for re-dispersing fine copper particles (P) in the disperse medium (S), it is preferable to adopt an ultrasonic wave irradiating method.

Primary particles of fine copper particles (Pc) produced by reduction are to have an averaged particle diameter of 1 to 150 nm, and preferably 1 to 100 nm in practical use. Here, primary particle diameters refer to diameters of primary particles of individual fine particles of metals and the like constituting secondary particles. It is possible to measure primary particle diameters by a transmission electron microscope. Further, the term “averaged particle diameter” means a number-average particle diameter of fine particles of metals and the like. Note that secondary particles refer to those particles formed by aggregation of primary particles in a disperse medium.

While fine copper particles (P) form secondary aggregates which are flocculates each including fine particles having primary particle diameters of 1 to 150 nm and attracted to one another by weak forces which allow for re-dispersion, it is possible to measure secondary aggregation sizes by a dynamic light-scattering-type particle size distribution measuring device. Since it is possible to obtain a fine particle dispersion having a higher particle dispersibility (smaller secondary aggregation sizes) by dispersing fine copper particles (P) into a disperse medium (S) including the organic solvent (A), organic solvent (B), and organic solvent (C), it is possible to easily cause an averaged secondary aggregation size of secondary aggregated particles to be 500 nm or less, and preferably 300 nm or less.

Note that control of an averaged particle diameter of primary particles of fine copper particles (P) can be performed by selection of kinds and adjustment of blending concentrations of copper ions, polymeric dispersant (D), and reducing agent, and by adjustments of stirring speed, temperature, time, pH, and the like upon reductive reaction of copper ions. Concretely, it is exemplarily possible to obtain fine copper particles having an averaged particle diameter of 100 nm for primary particles in case of electroless liquid phase reduction, by achieving a reduction temperature of about 80° C. upon reduction of copper ions (cupric acetate or the like) by sodium borohydride in an aqueous solution in the presence of polyvinyl pyrrolidone (PVP; number-average molecular weight of about 3,500).

Polymeric Dispersant (D):

The polymeric dispersant (D) has a solubility in water, and has a function to be present in a manner to cover surfaces of fine particles such as made of metals in a solvent to thereby restrict aggregation of fine copper particles, thereby excellently keeping dispersibility thereof.

In case that fine copper particles (P) are produced by liquid phase reduction of copper ions in an aqueous solution such as by electrolytic reduction or by electroless reduction using a reducing agent, for example, the polymeric dispersant (D) of the present invention allows for effective formation of fine copper particles (P), by dissolving the water-soluble polymeric dispersant (D) in the aqueous solution to thereby restrict aggregation of fine copper particles (P) to be deposited by a reductive reaction.

The polymeric dispersant (D) of the present invention is water-soluble, and has a function to restrict aggregation of fine copper particles (P) to thereby excellently keep dispersibility thereof when the polymeric dispersant is present in a manner to cover surfaces of fine copper particles (P) deposited in a reaction system.

In case of forming fine copper particles (P) in an aqueous solution by liquid phase reduction in the presence of the polymeric dispersant (D), the polymeric dispersant (D) has solubility in water and is present in a manner to cover surfaces of deposited fine copper particles (P) to thereby restrict aggregation of fine particles (P) of metals or the like, thereby keeping dispersion thereof.

Usable as the polymeric dispersant (D) are any dispersants which each have a molecular weight of about 100 to 100,000 depending on a chemical structure thereof, each have a solubility in water, and are each capable of excellently dispersing fine particles of metals and the like deposited from metal ions by reductive reaction in an aqueous solution.

Desirable as the polymeric dispersant (D) is one kind or two or more kinds selected from among: amine-based polymers such as polyvinyl pyrrolidone, polyethyleneimine; hydrocarbon-based polymers having carboxylic acid groups, such as polyacrylic acids, carboxy methyl cellulose; acrylamides such as polyacrylamides; polyvinyl alcohols; polyethylene oxides; starches; and gelatins.

Concrete examples of molecular weights of the above exemplified polymeric dispersant (D) compounds include polyvinyl pyrrolidones (molecular weights: 1,000 to 500,000), polyethyleneimines (molecular weights: 100 to 100,000), carboxy methyl celluloses (substitution degrees of sodium hydroxylates of alkali cellulose, into carboxymethyl groups: 0.4 or more; and molecular weights: 1,000 to 100,000), polyacrylamides (molecular weights: 100 to 6,000,000), polyvinyl alcohols (molecular weights: 1,000 to 100,000), polyethylene glycols (molecular weights: 100 to 50,000), polyethylene oxides (molecular weights: 50,000 to 900,000), gelatins (averaged molecular weights: 61,000 to 67,000), water-soluble starches, and the like.

Described in the parentheses are number-average molecular weights of the polymeric dispersants (D), respectively, and the dispersants within such molecular weight ranges have water-solubility and are thus preferably usable in the present invention. Note that two or more kinds of them can be used combinedly.

Other examples include thiols, carboxylic acids, amides, carbonitrile, esters, and the like. Further examples include polymethyl vinyl ethers, as polymers having polar groups.

The above-described aggregating agent is not particularly limited, insofar as the same is liquid or gaseous at an ordinary temperature or operating temperature, will aggregate or precipitate fine particles by addition of the aggregating agent into an aqueous solution after a reductive reaction, and will not deposit the polymeric dispersant (D). However, preferable examples thereof include halogen-based hydrocarbons, and the like. Desirable as the halogen-based hydrocarbons are: halogen compounds such as chlorine compounds, bromine compounds, and the like each having a carbon atom number of 1 to 4; and halogen-based aromatic compounds such as chlorine-based and bromine-based ones.

In the above manner, there can be obtained a dispersion, having an improved dispersibility, of: fine copper particles having surfaces free of coating of the polymeric dispersant (D) or having surfaces coated with an extremely small amount of the polymeric dispersant (D) such that the weight ratio (D/P) between the polymeric dispersant (D) and fine copper particles (P) is less than 0.001; or fine copper particles having surfaces coated with a relatively small amount of the polymeric dispersant (D) such that the weight ratio (D/P) between the polymeric dispersant (D) and fine copper particles (P) is within a range of 0.001 to 0.01.

It is possible to confirm the weight ratio (D/P) between the polymeric dispersant (D) covering surfaces of the fine copper particles (P) and the fine copper particles (P) themselves, by the following method (i) or (ii).

(i) There is collected a sample of the fine particle dispersion; fine copper particles (P) are separated from the sampled fine copper particle dispersion by an operation such as centrifugal separation; there is prepared a solution including copper particles dissolved therein under a condition that the polymeric dispersant (D) does not react; and the solution is quantitatively analyzed by liquid chromatography or the like, thereby measuring a weight ratio (D/P). Note that the detection limit of the polymeric dispersant (D) by this analyzing method can be made to be about 0.02 wt %.

(ii) There is collected a sample of the fine particle dispersion; fine copper particles (P) are separated from the sampled fine copper particle dispersion by an operation such as centrifugal separation; the polymeric dispersant (D) is extracted from fine copper particles (P) into a solvent, such as by an operation of solvent extraction, followed by a concentrating operation such as evaporation if required; and the extract is analyzed by liquid chromatography, or specific elements (nitrogen, sulfur, and the like) in the polymeric dispersant (D) can be analyzed by X-ray photoelectron spectroscopy (XPS), Auger Electron Spectroscopy (AES), or the like.

(Forming Step of Wiring Pattern)

Next, the fine copper particle dispersion obtained by the above step is coated or printed onto a substrate, thereby forming a wiring pattern comprising a liquid film of the fine copper particle dispersion.

Although it is possible to adopt conventionally known various methods as the coating or printing method, it is desirable to adopt an inkjetting or screen printing method.

Usable as the substrate are transparent plastic materials such as polyethylene terephthalate (PET), triacetylcellulose (TAC), polycarbonate (PC), polymethylmethacrylate (PMMA), and the like.

(Firing Step)

Next, the liquid film of the fine copper particle dispersion is dried and fired, to form a sintered wiring layer of fine copper particles.

At this time, since fine copper particles have surfaces free of coating of the polymeric dispersant (D) or have surfaces coated with a relatively small amount of the polymeric dispersant (D), sintering among fine copper particles themselves is not obstructed unlike conventional fine copper particles coated with thick layers of polymeric compound, thereby enabling firing at a relatively low temperature on the order of 190° C.

Concretely, the drying condition is 100 to 200° C. for about 15 to 30 minutes depending on solvents to be used, for example, and the firing condition is 190 to 250° C. for about 20 to 40 minutes, and preferably 190 to 220° C. for about 20 to 40 minutes depending on coating thicknesses, for example.

Drying and firing can be performed in an atmosphere of inert gas such as argon, without using a reducing gas such as hydrogen gas.

(Forming Step of Black-Colored Layer)

Next, there is formed a black-colored layer on the sintered wiring of fine copper particles. The black-colored layer can be formed by coating or printing a pigment dispersion including a black-colored inorganic pigment onto the sintered wiring in an overlapping manner. The coating or printing method is preferably an inkjetting or screen printing method.

In addition to the aforementioned forming methods, it is possible to directly form a black-colored layer on a substrate, to coat or print a fine copper particle dispersion onto the layer to thereby form a wiring pattern comprising a liquid film of the fine copper particle dispersion, and to fire the liquid film to thereby form a sintered wiring layer. Further, it is possible to form a second black-colored layer on the sintered wiring layer.

Usable as the black-colored inorganic pigment are fine particles comprising various inorganic materials exhibiting a black color, and examples thereof include fine particles of oxides or carbides of at least one kind of metal selected from a group consisting of copper, cobalt, chromium, manganese, iron, ruthenium, and titanium, for example. It is further possible to use various carbon blacks, which are typically used, as black coloring agents.

Although disperse media for dispersing therein black-colored inorganic pigments are not particularly limited, it is desirable to use water, alcohols, hydrocarbons, and ethers, and particularly water and hydrocarbons, from a standpoint of dispersion stability of fine particles and readiness of application to an inkjetting method. These media can be used solely, or combinedly in two or more kinds.

Examples of applicable alcohols include methanol, ethanol, propanol, butanol, and the like.

Examples of applicable hydrocarbons include n-heptane, n-octane, decane, toluene, xylene, cymene, durene, indene, dipentene, tetrahydronaphthalene, cyclohexylbenzene, and the like.

Examples of applicable ethers include ethylene glycol dimethyl ether, ethylene glycol diethyl ether, ethylene glycol methylethyl ether, diethylene glycol dimethyl ether, diethylene glycol diethyl ether, diethylene glycol methylethyl ether, 1,2-dimethoxyethane, bis(2-methoxyethyl) ether, p-dioxane, and the like.

The pigment dispersion coated or printed onto the substrate is then dried and subjected to a heat treatment, to form a sintered wiring having a two-layer structure comprising a sintered wiring layer and a black-colored layer.

Forming the sintered wiring having the two-layer structure comprising the sintered wiring layer and black-colored layer in this way, allows for obtainment of a wiring having an excellent electrical conductivity, as compared with a case of forming a sintered wiring of single black-colored layer by coating a dispersion including fine copper particles and black-colored inorganic pigment onto a substrate followed by firing, for example. This resultingly enables formation of a wiring having a smaller width, thereby enabling application to a finer wiring pattern.

The above steps form an electromagnetic wave shielding wiring circuit adopting copper, the metal material for which is remarkably inexpensive in itself as compared with gold, silver, nickel, and the like, and which wiring circuit is free of occurrence of short circuit among wirings to be otherwise caused due to electromigration such as upon usage of silver.

The obtained electromagnetic wave shielding wiring circuit is excellent in electrical conductivity even by low-temperature firing, and is capable of achieving its electrical resistance of 1×10⁻⁴Ωcm or less, thereby enabling to exhibit an excellent shielding capability. Further, since the sintered wiring layer in the present invention is also excellent in adherence to a substrate, it is particularly desirable to form a sintered wiring layer on a substrate by the applicable one of the above forming methods.

Further, by adopting the electromagnetic wave shielding wiring circuit forming method of the present invention, it becomes possible to decrease a production cost of an electromagnetic wave shielding sheet, thereby contributing to a decreased cost of electric equipments such as a plasma display panel having the electromagnetic wave shielding sheet installed thereon.

### Second Embodiment

There will be explained an electromagnetic wave shielding wiring circuit forming method according to a second embodiment of the present invention.

(Preparing Step of Fine Copper Particle Dispersion)

There is firstly performed a preparing step of a fine copper particle dispersion. The methods for preparing constituent components of the fine copper particle dispersion are the same as the first embodiment.

(Forming Step of Wiring Pattern)

Next, the fine copper particle dispersion is coated or printed onto a substrate in the same manner as the first embodiment, to form a wiring pattern comprising a liquid film of the fine copper particle dispersion.

(Coating or Printing Step of Pigment Dispersion)

Next, overlappedly coated or printed onto the liquid film of the fine copper particle dispersion is a pigment dispersion including a black-colored inorganic pigment. Usable as the coating or printing method is an inkjetting or screen printing method.

For example, in case of utilizing an inkjetting method, two inkjet nozzles are adopted in a manner to coat the pigment dispersion by the first nozzle, and to successively discharge a fine copper particle dispersion thereafter. At this time, the fine copper particle dispersion may be discharged, after performing a drying step after coating the pigment dispersion.

Contrary, it is possible to discharge the fine copper particle dispersion by the first inkjet nozzle, and to successively discharge the pigment dispersion by the second inkjet nozzle. Although it is possible to coat the pigment dispersion in a manner overlapped onto a liquid film of the fine copper particles because the firstly discharged fine copper particle dispersion is immediately dried to a certain extent and brought into the liquid film of fine copper particles, it is also possible to perform a drying step after discharging the fine copper particle dispersion and to thereafter coat the pigment dispersion in an overlapped manner.

(Firing Step)

Next, the thin-film of fine copper particle dispersion and the pigment dispersion are dried and fired to form a sintered wiring having a two-layer structure comprising a sintered copper layer and a black-colored layer. The firing temperature is preferably 190° C. to 300° C.

At this time, firing is possible at a relatively low temperature of about 190° C., and drying and firing can be performed in an atmosphere of inert gas such as argon without using a reducing gas such as a hydrogen gas, similarly to the first embodiment.

Note that, since the sintered wiring layer in the present invention is also excellent in adherence to a substrate, it is particularly desirable to form a sintered wiring layer on a substrate by the applicable one of the above forming methods, similarly to the forming method of the wiring according to the first embodiment.

In this way, simultaneously forming a sintered copper layer and a black-colored layer provides a more simplified production process of wiring, than the forming method of wiring according to the first embodiment for separately forming a sintered wiring of fine copper particles and a black-colored layer.

Also by the second embodiment, it is possible to realize a PDP-oriented wiring which is inexpensive and which uses copper free of occurrence of electromigration, similarly to the first embodiment. Further, the obtained PDP-oriented wiring is excellent in electrical conductivity even by low-temperature firing, and is capable of exhibiting an excellent shielding capability in case of usage as an electromagnetic wave shielding wiring. Furthermore, the sintered wiring layer is also excellent in adherence to a substrate. It is further possible to decrease a manufacturing cost of a plasma display panel, thereby contributing to a decreased cost of a plasma display panel.

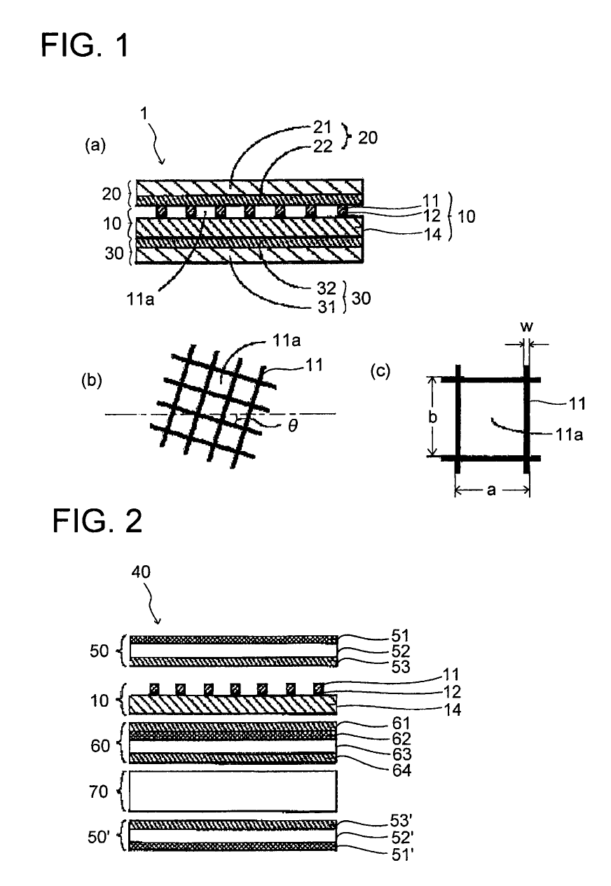

FIG. 1 shows an example of an electromagnetic wave shielding sheet including an electromagnetic wave shielding wiring circuit obtained by the first or second embodiment. As shown in FIG. 1(a), the electromagnetic wave shielding sheet 1 includes a laminated body 10 laminatingly including a transparent substrate film 14, a black-colored layer 12 in a meshed shape formed thereon, and a sintered wiring layer 11 formed thereon, and the sheet includes a protective film 20 and a protective film 30 provided on both surfaces of the laminated body 10, respectively. The protective film 20 includes a substrate 21 and an adhesive layer 22 formed thereon, and the protective film 30 includes a substrate 31 and an adhesive layer 32 formed thereon. Although the black-colored layer 12 is laminated at the transparent substrate film 14 side relative to the sintered wiring layer 11 in this example, it is possible that the sintered wiring layer 11 is arranged at the transparent substrate film 14 side.

Further, as shown in FIG. 1(b), the sintered wiring layer 11 in the electromagnetic wave shielding sheet 1 is formed with opening areas 11a densely arranged to exhibit a meshed shape. As shown in FIG. 1(c), each opening area 11a is defined by a peripheral line having a narrow width “w” of 5 μm to 20 μm. Further, although the longitudinal and latitudinal pitches “a” and “b” of the opening areas may be the same or different, they are about 50 μm to 500 μm in either case. Only, it is desirable that the opening ratio per unit area is about 90% to 95%. Further, the applicable lines may each have an appropriate angle θ relative to a horizontal direction (the horizontal direction during observation). Note that the “meshed shape” is not limited to the lattice shape shown in FIG. 1(b), and the opening area 11a may be exemplarily provided in hexagonal shapes for cooperatively defining a honeycomb configuration, or in circular shapes, elliptical shapes, or the like, which are all embraced in the meshed shapes.

Further, the electromagnetic wave shielding sheet 1 is used in such a manner that sheets having effects for strengthening outermost surfaces, providing antireflection properties, providing antifouling properties, and the like are laminated onto obverse and reverse surfaces of the laminated body 10 laminated on a substrate, respectively, via infrared light cutting filter layers against the laminated body 10, for example. Thus, the protective film 20 is required to be peeled upon such additional lamination, and it is therefore desirable that lamination of the protective film 20 to the sintered wiring layer 11 side is performed in a peelable manner.

Further, the peel strength of the protective film 20 upon lamination on the sintered wiring layer 11 is preferably 5 mN/25 mm width to 5N/25 mm width, and more preferably 10 mN/25 mm width to 100 mN/25 mm width. Peel strengths less than the lower limit lead to excessively easy peeling, thereby undesirably bringing about a possibility that the protective film 20 is accidentally peeled during handling or with inadvertent contact. Meanwhile, peel strengths exceeding the upper limit require larger forces for peeling, and undesirably bring about a possibility that the sintered wiring layer 11 in the meshed shape may be peeled from the transparent substrate film 14 upon peeling of the protective film.

FIG. 2 is a schematic view of an electromagnetic wave shielding panel adopting the electromagnetic wave shielding sheet of the present invention. In FIG. 2, the upper side is an observing side and the lower side is a back side. This electromagnetic wave shielding panel 40 is arranged at an observing side of a display such as a PDP (not shown). The electromagnetic wave shielding panel 40 includes: the laminated body 10 laminatingly including the transparent substrate film 14, the black-colored layer 12 formed on the film 14 (i.e., formed at the observing side), and the sintered wiring layer 11 in a meshed shape formed on the black-colored layer 12; and the electromagnetic wave shielding panel includes, at the side of the sintered wiring layer 11, a film 50 for the observing side (i.e., for a front surface), which film 50 laminatingly includes, in the order from the laminated body 10, an adhesive layer 53, a film 52, and a multi-layer 51, where the multi-layer 51 includes a hardcoat layer, an antireflective layer, an antifouling layer, and the like laminated sequentially. Actually, the laminated bodies 50, 10, 60, 70, and 50′ in FIG. 2 are laminated without spacings therebetween.

Sequentially laminated on the laminated body 10 at its transparent substrate film 14 side, are a near-infrared absorbing film 60, a glass substrate 70, and a back-surface-oriented (reverse-surface-oriented) film 50′. The near-infrared absorbing film 60 includes an adhesive layer 61, a near-infrared absorbing layer 62, a film 63, and an adhesive layer 64, sequentially laminated from the laminated body 10 side. The glass substrate 70 is provided for maintaining a mechanical strength, and a self-sustainability or planarity of the whole of electromagnetic wave shielding panel 40. The reverse-surface-oriented (back-surface-oriented) film 50′ includes an adhesive layer 53′, a film 52′, and a multi-layer 51′ sequentially laminated from the glass substrate 70 side, and where the multi-layer 51′ includes a hardcoat layer, an antireflective layer, an antifouling layer, and the like laminated sequentially, and where the reverse-surface-oriented film 50′ adopted in this case is the same as the observing-side-oriented film 50.

Note that the electromagnetic wave shielding panel 40 described with reference to FIG. 2 is merely exemplary, and it is desirable to laminate the above-described laminated bodies; however, it is possible to conduct a modification as required, in such a manner to omit any one of them, or to provide and use a laminated body combiningly possessing the functions of the respective layers, for example.

### Examples

Although Examples of the present invention will be described hereinafter, the present invention is not limited to such Examples.

Firstly, evaluation criteria in Examples and Comparative Examples will be described.

(1) Electrical Resistance of Wiring:

Electrical resistances of wirings were measured by a direct current four-terminal method (used measurement device: Digital Multimeter DMM2000 (four-terminal measurement mode) manufactured by Keithley Instruments Inc.). Evaluations of electrical resistances were based on the following criterion:

◯: less than 1×10⁻⁴ [Ω·cm]

Δ: larger than 1×10⁻⁴ [Ω·cm] and less than 10×10⁻² [Ω·cm]

x: larger than 1×10⁻² [Ω·cm]

(2) Adherence of Fired Film to Substrate:

There was conducted a tape peeling test of each fired film, in conformity to JIS D0202-1988. The applicable fired film of an evaluation sample was cut through at intervals of 1 mm and into 10 squares, and a cellophane tape (“CT24”, by NICHIBAN CO., LTD.) was used and closely contacted with an applicable film, followed by peeling. The judgment was indicated based on the following criterion, i.e., the number of squares which were not peeled from among the 10 squares.

◯: the number of peeled squares was 1 or less

Δ: the number of peeled squares was 4 to 2

x: the number of peeled squares was 5 or more

The electromagnetic wave shielding wiring circuit was formed by the following procedure.

1. Preparation of Fine Copper Particle Dispersion:

Fine copper particles covered with a polymeric dispersant were prepared by the following procedure.

There were prepared: 10 ml of a copper acetate water solution, by dissolving 0.2 g of copper acetate ((CH₃COO)2Cu.1H₂O) as a source material of fine copper particle, in 10 ml of distilled water; and 100 ml of sodium borohydride water solution, by dissolving sodium borohydride as a reducing agent for metal ions, in distilled water, in a manner to attain a concentration of 5.0 mol/liter. Thereafter, 0.5 g of polyvinyl pyrrolidone (PVP; number-average molecular weight of about 3,500) as a polymeric dispersant was further added into the sodium borohydride water solution, and dissolved therein by stirring.

The 10 ml of the copper acetate water solution was dropped into the water solution including the reducing agent and polymeric dispersant dissolved therein, in an atmosphere of nitrogen gas. This solution for reductive reaction was subjected to the reaction by sufficiently stirring the solution itself for about 60 minutes, thereby resultingly obtaining a fine particle dispersion including water and fine copper particles dispersed therein having an averaged particle diameter of 5 to 10 nm for primary particles.

Next, added into 100 ml of the dispersion including fine copper particles obtained by the above procedure, was 5 ml of chloroform as an agglomeration promoter, followed by sufficient stirring. After stirring for several minutes, the resultant dispersion was left stand still, and then its water phase as a reaction solution was supplied to a centrifuge, by which fine copper particles were separated and collected. Then, there were conducted water washing three times each in a manner to charge the obtained fine copper particles and 30 ml of distilled water into a test tube and to sufficiently stir them by an ultrasonic homogenizer, followed by collection of particle components by a centrifuge; and subsequently, there were conducted alcohol washing three times each in a manner to charge the obtained fine copper particles and 30 ml of 1-butanol similarly into a test tube and to sufficiently stir them, followed by collection of particle components by the centrifuge. By the above procedure, there were obtained fine copper particles to be dispersed into an eventual disperse medium.

Aside from the above, there were adopted N-methylacetamide as the organic solvent (A), diethyl ether as the organic solvent (B), ethylene glycol as the organic solvent (C), and triethylamine as the organic solvent (E) for examples of mixed organic solvents of the present invention, in a manner to mix them at solvent mixing ratios listed in Table 1 and Table 2, thereby preparing mixed organic solvents of Examples 1-1 to 1-25, respectively.

The fine copper particles obtained in the above procedure were dispersed into 10 ml of the mixed organic solvents 1-1 to 1-25, respectively, followed by application of ultrasonic vibrations to each dispersion for 1 hour by an ultrasonic homogenizer, thereby preparing fine copper particle dispersions of Examples 1-1 to 1-25.

Next, there was conducted analysis of polymeric dispersants, if any, covering the surfaces of fine copper particles. Firstly, poured onto the fine copper particles obtained by the above procedure, was an eluate prepared by mutually mixing 0.2 M of nitric acid water solution, 0.2 M of hydrochloric acid water solution, and methanol at a ratio of 1:1:2, thereby dissolving the copper particle component. The thus obtained solution was neutralized by an appropriate amount of sodium hydroxide water solution, followed by measurement of a content of the polymeric dispersant component by a gel permeation chromatogram (GPC; detector; Shodex RI SE-61; and column: Tosoh TSKgel G3000PWXL) made by SHOWA DENKO K.K. As a result, the used polymeric dispersant component (polyvinyl pyrrolidone) was not detected at all. Note that the detection limit of the used measuring device was 0.02 wt %.

Based on this experiment result and the detection sensitivity of the measuring device, it was confirmed that the amount of polymeric dispersant (D) attached to fine copper particles obtained by this production method was at least less than 0.001, in terms of a weight ratio (D/P) relative to an amount of fine copper particles (P).

2. Step of Forming Wiring Pattern:

Respectively charged into a first inkjet head and a second inkjet head (made by Mect Co., Ltd.: MICROJET (Trademark) Model MJ-040) were: (i) an ink (black-colored inorganic pigment ink) obtained by dispersing an electroconductive carbon black (Ketchen Black (Trademark)) as a black-colored inorganic pigment into THF (tetrahydrofuran) at 3 wt %; and (ii-1) each of the fine copper particle dispersions (Examples 1-1 to 1-25) prepared by the procedure described in the item 1., (ii-2) a copper nano particle dispersion (product name: Cu nanometal ink “CulT”) made by ULVAC, Inc., as Comparative Example 1, (ii-3) a fine copper particle dispersion prepared by dispersing the fine copper particles obtained by the above procedure into distilled water, as Comparative Example 2, or (ii-4) each of fine copper particle dispersions prepared by dispersing the fine copper particles obtained by the above procedure into solvents at mixing ratios listed in Table 3, as Comparative Examples 3-1 to 3-7, respectively. Subsequently formed by the black-colored inorganic pigment ink was a pattern onto a transparent polyethylene terephthalate (PET) resin film (manufactured by TOYOBO Co., Ltd.; product number: A4300) having a width of 700 mm and a thickness of 100 μm, and the formed pattern was dried by holding it in an atmosphere of argon gas at about 150° C. for 30 minutes, followed by formation of a pattern of a fine copper particle dispersion (A) on the dried pattern. The pattern at this time was formed such that each opening area 11a was defined by a peripheral line having a width “w” of 10 μm and longitudinal and latitudinal pitches “a” and “b” were 250 μm, respectively, as shown in FIG. 1(c).

3. Step of Forming Sintered Wiring Layer:

The wiring pattern formed in the step 2 was held at about 150° C. for 30 minutes in an atmosphere of argon gas to dry the coated film, and subjected to one-hour heat treatments at 180° C., 190° C., 210° C., 250° C., and 300° C., respectively, in an atmosphere of nitrogen. Thereafter, the wiring pattern was subjected to furnace cooling in a heat-treatment furnace, gradually down to a room temperature.

Based on the above, there were formed electromagnetic wave shielding wiring circuits of Examples and Comparative Examples, respectively.

(Evaluation of Electrical Conductivity)

Shown in Table 1 to Table 3 are results of measurements of wirings obtained in Examples and Comparative Examples after sintering.

| | | Example No. | | | | | | | | | | | | |
|---|---|---|---|---|---|---|---|---|---|---|---|---|---|---|
| | | | | | | | | | | | 1- | 1- | 1- | 1- |
| | | 1-1 | 1-2 | 1-3 | 1-4 | 1-5 | 1-6 | 1-7 | 1-8 | 1-9 | 10 | 11 | 12 | 13 |
| (1) Solvent mixing ratio | | S1 | | | | | | S2 | | | | | | S3 |
| N-methylacetamide | (vol %) | 5 | 10 | 90 | 40.0 | 45.0 | 10 | 5 | 20 | 50 | 60 | 80 | 95 | 0 |
| Dimethyl ether | (vol %) | 5 | 10 | 5 | 20.0 | 45.0 | 40 | 0 | 0 | 0 | 0 | 0 | 0 | 0 |
| Ethylene glycol | (vol %) | 90 | 80 | 5 | 40.0 | 10.0 | 50 | 95 | 80 | 50 | 40 | 20 | 5 | 100 |

| (2) Evaluation result | | | | | | | | | | | | | | |
|---|---|---|---|---|---|---|---|---|---|---|---|---|---|---|
| Electrical | Sintering temperature: | Δ | Δ | Δ | Δ | Δ | Δ | ◯ | Δ | Δ | Δ | Δ | Δ | ◯ |
| Resistance | 180° C. | | | | | | | | | | | | | |
| | Sintering temperature: | ◯ | ◯ | Δ | ◯ | Δ | ◯ | ◯ | ◯ | ◯ | ◯ | ◯ | Δ | ◯ |
| | 190° C. | | | | | | | | | | | | | |
| | Sintering temperature: | ◯ | ◯ | ◯ | ◯ | ◯ | ◯ | ◯ | ◯ | ◯ | ◯ | ◯ | ◯ | ◯ |
| | 210° C. | | | | | | | | | | | | | |
| | Sintering temperature: | ◯ | ◯ | ◯ | ◯ | ◯ | ◯ | ◯ | ◯ | ◯ | ◯ | ◯ | ◯ | ◯ |
| | 250° C. | | | | | | | | | | | | | |
| | Sintering temperature: | ◯ | ◯ | ◯ | ◯ | ◯ | ◯ | ◯ | ◯ | ◯ | ◯ | ◯ | ◯ | ◯ |
| | 300° C. | | | | | | | | | | | | | |

| | | | | | | | | | | | | | |
|---|---|---|---|---|---|---|---|---|---|---|---|---|---|
| Peeling test result | ◯ | ◯ | ◯ | ◯ | ◯ | ◯ | Δ | ◯ | ◯ | ◯ | ◯ | ◯ | Δ |

| | | Example No. | | | | | | | | | | | |
|---|---|---|---|---|---|---|---|---|---|---|---|---|---|
| | | 1- | 1- | 1- | 1- | 1- | 1- | 1- | 1- | 1- | 1- | 1- | 1- |
| | | 14 | 15 | 16 | 17 | 18 | 19 | 20 | 21 | 22 | 23 | 24 | 25 |
| (1) Solvent mixing ratio | | S4 | | S5 | | | | | | S6 | | | |
| N-methylacetamide | (vol %) | 28 | 15 | 50 | 30 | 60 | 80 | 35 | 17 | 0 | 0 | 0 | 0 |
| Dimethyl ether | (vol %) | 10 | 35 | 0 | 0 | 0 | 0 | 0 | 0 | 0 | 0 | 0 | 0 |
| Ethylene glycol | (vol %) | 60 | 40 | 40 | 40 | 35 | 17 | 60 | 80 | 90 | 95 | 80 | 65 |
| Triethylamine | (vol %) | 2 | 10 | 10 | 30 | 5 | 3 | 5 | 3 | 10 | 5 | 20 | 35 |

| (2) Evaluation result | | | | | | | | | | | | | |
|---|---|---|---|---|---|---|---|---|---|---|---|---|---|
| Electrical | Sintering temperature: | Δ | Δ | Δ | Δ | Δ | Δ | Δ | Δ | Δ | ◯ | Δ | Δ |
| Resistance | 180° C. | | | | | | | | | | | | |
| | Sintering temperature: | ◯ | ◯ | ◯ | ◯ | ◯ | Δ | ◯ | ◯ | ◯ | ◯ | ◯ | ◯ |
| | 190° C. | | | | | | | | | | | | |
| | Sintering temperature: | ◯ | ◯ | ◯ | ◯ | ◯ | ◯ | ◯ | ◯ | ◯ | ◯ | ◯ | ◯ |
| | 210° C. | | | | | | | | | | | | |
| | Sintering temperature: | ◯ | ◯ | ◯ | ◯ | ◯ | ◯ | ◯ | ◯ | ◯ | ◯ | ◯ | ◯ |
| | 250° C. | | | | | | | | | | | | |
| | Sintering temperature: | ◯ | ◯ | ◯ | ◯ | ◯ | ◯ | ◯ | ◯ | ◯ | ◯ | ◯ | ◯ |
| | 300° C. | | | | | | | | | | | | |

| | | | | | | | | | | | | |
|---|---|---|---|---|---|---|---|---|---|---|---|---|
| Peeling test result | ◯ | ◯ | ◯ | ◯ | ◯ | ◯ | ◯ | ◯ | ◯ | Δ | ◯ | Δ |

| | | Comparative Example No. | | | | | | | | |
|---|---|---|---|---|---|---|---|---|---|---|
| | | 1 | 2 | 3-1 | 3-2 | 3-3 | 3-4 | 3-5 | 3-6 | 3-7 |
| (1) Solvent mixing ratio | | | | | | | | | | |
| N-methylacetamide | (vol %) | Copper | — | 70 | 17 | 98 | 60 | 20 | 0 | 0 |
| Dimethyl ether | (vol %) | nanoparticie | — | 30 | 80 | 0 | 30 | 0 | 30 | 0 |
| Ethylene glycol | (vol %) | made by | — | 0 | 3 | 2 | 0 | 20 | 0 | 40 |
| Triethylamine | (vol %) | ULVAC, Inc. | — | 0 | 0 | 0 | 10 | 60 | 70 | 60 |
| Distilled water | (vol %) | | 100 | — | — | — | — | — | — | — |

| (2) Evaluation result | | | | | | | | | | |
|---|---|---|---|---|---|---|---|---|---|---|
| Electrical | Sintering temperature: | X | X | X | X | X | X | X | X | X |
| Resistance | 180° C. | | | | | | | | | |
| | Sintering temperature: | X | X | X | X | X | X | X | X | X |
| | 190° C. | | | | | | | | | |
| | Sintering temperature: | X | X | X | X | X | X | Δ | X | Δ |
| | 210° C. | | | | | | | | | |
| | Sintering temperature: | X | X | Δ | Δ | Δ | Δ | Δ | Δ | Δ |
| | 250° C. | | | | | | | | | |
| | Sintering temperature: | ≧ | X | Δ | Δ | Δ | Δ | Δ | Δ | Δ |
| | 300° C. | | | | | | | | | |

As apparent from Table 1 and Table 2, the fine copper particle dispersions of Examples 1-1 to 1-25 were allowed to be matured into wirings having excellent electrical conductivity, by heat treatments at temperatures of 210° C. or higher in an atmosphere of nitrogen, respectively. Particularly, it was further recognized that, electrical resistances were excellent even by a lower sintering temperature of 180° C. such as in cases of contents of 95 vol % or more of the organic solvent (C) (Examples 1-7, 1-13, and 1-23), and electrical resistances were not so excellent at lower sintering temperatures of 180° C. and 190° C. in cases of contents less than 20 vol % of the organic solvent (C).

Meanwhile, as apparent from Table 3, fired films obtained in Comparative Examples still had higher resistances even by achievement of heat treatments at temperatures of 250° C. or higher.

(Evaluation of Adherence)

Fired films were formed in the following procedure.

Fine copper particle dispersions were prepared in the same manner as the formation of the electromagnetic wave shielding wiring circuits, such that the fine copper particle dispersions of Examples 1-1 to 1-25 and Comparative Example 1, 2, 3-1 to 3-7 listed in Table 1 to Table 3 were each coated onto a transparent polyethylene terephthalate (PET) resin film (manufactured by TOYOBO Co., Ltd.; product number: A4300) of 2 cm×2 cm size and 100 μm thickness. The coated films were subsequently dried by holding them at about 150° C. for 30 minutes in an atmosphere of argon gas, followed by one-hour heat treatment at 210° C. in an atmosphere of nitrogen. They were subsequently subjected to furnace cooling gradually down to a room temperature.

There was conducted a tape peeling test for the fired films obtained by the above-described procedure.

The test results are listed in Table 1 to Table 3. As apparent from Table 1 and Table 2, the fired films obtained from the fine copper particle dispersions of Examples 1-1 to 1-25 were excellent in adherence. However, it was recognized that adherence was not so excellent in such cases that contents of the organic solvent (C) were 95 vol % or more (Example 1-7, 1-13, and 1-23) where electrical resistances were excellent in electrical conductivity evaluation even by the lower sintering temperature of 180° C.

Meanwhile, as apparent from Table 3, the fired films from the fine copper particle dispersions of Comparative Examples were insufficient in adherence.

As apparent from the above, using disperse media including the organic solvents (A) to (E) blended within ranges of the predetermined ratios, allowed for formation of electroconductive materials simultaneously possessing electrical conductivity and adherence.

(Evaluation of Stability of Ink)

There will be explained results of evaluation for storage stability of the fine copper particle dispersions used in Examples.

The fine copper particle dispersions were each stored for one month at 35° C. in a hermetically sealed state, to evaluate storage stability thereof. As a result, no precipitations were found in the fine copper particle dispersions.

Further, concerning mixtures prepared by adding electroconductive carbon black (Ketchen Black (Trademark)) of a black-colored inorganic pigment into fine copper particle dispersions, storage stabilities were evaluated by storing them each for one month at 35° C. in a hermetically sealed state. As a result, precipitation was caused in the mixture prepared by adding a black-colored inorganic pigment (electroconductive carbon black) ink into the fine copper particle dispersion (A). Similarly, precipitation was also caused in the fine copper particle dispersion (B).

The precipitations were each subjected to analysis by energy dispersive X-ray spectroscopy (EDS), thereby confirming strong peaks of C and Cu. It was considered that the electroconductive carbon black of the black-colored inorganic pigment ink and the copper particles were aggregated and precipitated.

Note that, when the applicable fine copper particle dispersion including the precipitation caused in the above manner was filled into an inkjet head, clogging of the nozzle is to be caused to disable conduction of wiring formation to thereby necessitate replacement of the head, so that such a fine copper particle dispersion is practically unusable.

It is therefore understood that, to form an electromagnetic wave shielding sheet having an excellent electrical conductivity without clogging of a nozzle of an inkjet head, it is effective to form a wiring by filling a black-colored inorganic pigment ink and a fine copper particle dispersion into separate inkjet heads, respectively, in the manners of Examples.

(Electromagnetic Wave Shielding Sheet)

Each of the fine copper particle dispersions of Examples and the black-colored inorganic pigment ink were used to form a black-colored layer 12 and a sintered wiring layer 11 on a transparent substrate film (PET film) 14 to obtain an electromagnetic wave shielding wiring circuit 10 as shown in FIG. 1. Although the layer thickness of the obtained sintered wiring layer 11 is not particularly limited, it is typically within a range of 0.5 to 100 μm. The thickness of the electroconductive layer is to be preferably established within a range of 0.5 to 100 μm, because excessively smaller thicknesses undesirably lead to a deteriorated electromagnetic-wave shieldabilities, and excessively larger thicknesses adversely affect thicknesses of obtained electromagnetic-wave shielding and light transmitting materials and may narrow viewing angles. Further, line widths of the electroconductive layers are preferably 5 to 20 μm, and particularly preferably 5 to 15 μm. Decreasing line widths enables restriction of occurrence of moire against pixels of a display, and also enables increased opening ratios for improving transparency.

Next, onto that side of the PET film 14 of the electromagnetic wave shielding wiring circuit 10 which was not formed with the black-colored layer 12 and sintered wiring layer 11, there was adhered a protective film 30 (made by Panac Industries, Inc.; product number: HT-25) having a total thickness of 28 μm by a laminator roller, which protective film was obtained by laminating an acrylic-based adhesive layer 32 to a PET film 31 and by applying a corona discharge treatment to that side of the PET film which did not include an adhesive layer laminated thereon. This resulted in a laminated body having a constitution of protective film 30/PET film 14/black-colored layer 12/sintered wiring layer (copper mesh) 11. Further, onto the sintered wiring layer 11 side of the thus obtained laminated body, there was adhered a protective film 20 (made by Sun A Kaken Co., Ltd.; product number: SUNYTECT Y-26F) having a total thickness of 65 μm by a laminator roller, which protective film was obtained by laminating an acrylic-based adhesive layer 22 to a polyethylene film 21. In the above manner, there was obtained an electromagnetic wave shielding sheet 1 having a constitution of protective film 30/PET film 14/black-colored layer 12/sintered wiring layer (copper mesh) 11/protective film 20 as shown in FIG. 1.

As described above, the electromagnetic wave shielding sheet of the present invention is excellent in electromagnetic-wave shieldability, substantially without occurrence of moire, and has a higher opening ratio to exhibit an improved transparency. Thus, the electromagnetic wave shielding sheet of the present invention is suitable as a front surface film of a PDP, and can be advantageously utilized in applications (such as adhesive films) for those environments such as hospitals, and university research facilities where electromagnetic-wave shieldability is required.

### EFFECT OF THE INVENTION

As described above, by the electromagnetic wave shielding wiring circuit forming method of the present invention, the electromagnetic wave shielding wiring circuit is formed by a fine copper particle dispersion, prepared by dispersing fine copper particles into a disperse medium (S) including an organic solvent (A) having an amide-based compound, an organic solvent (B) having a boiling point of 20° C. or higher at an ordinary pressure and having a donor number of 17 or more, an organic solvent (C) having a boiling point exceeding 100° C. at an ordinary pressure and comprising alcohol and/or polyhydric alcohol, and an organic solvent (E) having an amine-based compound, at specific ratios. Dispersing fine copper particles into such a disperse medium including the specific organic solvents, enables to improve a dispersibility of fine particles without coats of polymeric compounds on surfaces of fine copper particles or only with coats of relatively small amounts of polymeric compounds on surfaces of fine copper particles, thereby allowing for stabilized coating or printing of the fine copper particle dispersion onto a substrate. Further, using the fine copper particle dispersion without coats of polymeric compounds on surfaces of fine copper particles or only with coats of relatively small amounts of polymeric compounds on surfaces of fine copper particles, enables to eliminate or mitigate the factor which obstructs sintering among fine copper particles themselves, thereby enabling low-temperature firing. This enables realization of the electromagnetic wave shielding wiring circuit, applicable to a plastic substrate having a lower heat-resistance temperature, and utilizing copper which is inexpensive and free of occurrence of electromigration. The electromagnetic wave shielding wiring circuit formed by the electromagnetic wave shielding wiring circuit forming method of the present invention, is excellent in electrical conductivity even by low-temperature firing, and is capable of exhibiting an excellent shielding capability. Further, by adopting the electromagnetic wave shielding wiring circuit forming method of the present invention, it becomes possible to decrease a production cost of an electromagnetic wave shielding sheet, thereby contributing to a decreased cost of electric equipments such as a plasma display panel having the electromagnetic wave shielding sheet installed thereon.

What is claimed is:

1. An electromagnetic wave shielding wiring circuit forming method comprising the steps of:
preparing a fine copper particle dispersion, by dispersing fine copper particles (P) into a disperse medium (s) selected from:
(i) a disperse medium (S1) including an organic solvent (A) having an amide-based compound, an organic solvent (B) having a boiling point of 20° C. or higher at an ordinary pressure and having a donor number of 17 or more, and an organic solvent (C) having a boiling point exceeding 100° C. at an ordinary pressure and comprising alcohol and/or polyhydric alcohol;
(ii) a disperse medium (S2) including an organic solvent (A) having an amide-based compound, and an organic solvent (C) having a boiling point exceeding 100° C. at an ordinary pressure and comprising alcohol and/or polyhydric alcohol;
(iii) a disperse medium (S3) including organic solvent (C) having a boiling point exceeding 100° C. at an ordinary pressure and comprising alcohol and/or polyhydric alcohol;
(iv) a disperse medium (S4) including 24 to 64 vol % of an organic solvent (A) having an amide-based compound, 5 to 39 vol % of a low-boiling organic solvent (B) having a boiling point between 20° C. and 100° C. at an ordinary pressure, 30 to 70 vol % of an organic solvent (C) having a boiling point exceeding 100° C. at an ordinary pressure and comprising alcohol and/or polyhydric alcohol, and 1 to 40 vol % of an organic solvent (E) having an amine-based compound;
(v) a disperse medium (S5) including 30 to 94 vol % of an organic solvent (A) having an amide-based compound, 30 to 94 vol % of an organic solvent (C) having a boiling point exceeding 100° C. at an ordinary pressure and comprising alcohol and/or polyhydric alcohol, and 1 to 40 vol % of an organic solvent (E) having an amine-based compound; and
(vi) a disperse medium (S6) including 60 to 99 vol % of an organic solvent (C) having a boiling point exceeding 100° C. at an ordinary pressure and comprising alcohol and/or polyhydric alcohol, and 1 to 40 vol % of an organic solvent (E) having an amine-based compound;
coating or printing the fine copper particle dispersion onto a substrate or a black-colored layer formed on the substrate, to form a wiring pattern comprising a liquid film of the fine copper particle dispersion; and
firing the liquid film of the fine copper particle dispersion, to form a sintered wiring layer.

2. The electromagnetic wave shielding wiring circuit forming method of claim 1, further comprising the step of: forming a black-colored layer on the sintered wiring layer.

3. The electromagnetic wave shielding wiring circuit forming method of claim 2, wherein the black-colored layer is formed by coating or printing a pigment dispersion including a black-colored inorganic pigment overlappingly onto the substrate or the sintered wiring layer.

4. The electromagnetic wave shielding wiring circuit forming method of any one of claims 1 to 3, wherein the coating or printing is conducted by an inkjetting or screen printing method, respectively.

5. An electromagnetic wave shielding wiring circuit forming method comprising the steps of:
preparing a fine copper particle dispersion, by dispersing fine copper particles (P) into a disperse medium (s) selected from:
(i) a disperse medium (S1) including an organic solvent (A) having an amide-based compound, an organic solvent (B) having a boiling point of 20° C. or higher at an ordinary pressure and having a donor number of 17 or more, and an organic solvent (C) having a boiling point exceeding 100° C. at an ordinary pressure and comprising alcohol and/or polyhydric alcohol;
(ii) a disperse medium (S2) including an organic solvent (A) having an amide-based compound, and an organic solvent (C) having a boiling point exceeding 100° C. at an ordinary pressure and comprising alcohol and/or polyhydric alcohol;
(iii) a disperse medium (S3) including organic solvent (C) having a boiling point exceeding 100° C. at an ordinary pressure and comprising alcohol and/or polyhydric alcohol;
(iv) a disperse medium (S4) including 24 to 64 vol % of an organic solvent (A) having an amide-based compound, 5 to 39 vol % of a low-boiling organic solvent (B) having a boiling point between 20° C. and 100° C. at an ordinary pressure, 30 to 70 vol % of an organic solvent (C) having a boiling point exceeding 100° C. at an ordinary pressure and comprising alcohol and/or polyhydric alcohol, and 1 to 40 vol % of an organic solvent (E) having an amine-based compound;
(v) a disperse medium (S5) including 30 to 94 vol % of an organic solvent (A) having an amide-based compound, 30 to 94 vol % of an organic solvent (C) having a boiling point exceeding 100° C. at an ordinary pressure and comprising alcohol and/or polyhydric alcohol, and 1 to 40 vol % of an organic solvent (E) having an amine-based compound; and
(vi) a disperse medium (S6) including 60 to 99 vol % of an organic solvent (C) having a boiling point exceeding 100° C. at an ordinary pressure and comprising alcohol and/or polyhydric alcohol, and 1 to 40 vol % of an organic solvent (E) having an amine-based compound;
(a) coating or printing the fine copper particle dispersion onto a substrate, to form a wiring pattern comprising a liquid film of the fine copper particle dispersion;
(b) coating or printing a pigment dispersion including a black-colored inorganic pigment, overlappingly onto the liquid film of the fine copper particle dispersion; and
firing the liquid film of the fine copper particle dispersion and the pigment dispersion, to form a sintered wiring having a two-layer structure comprising a sintered copper layer and a black-colored layer.

6. The electromagnetic wave shielding wiring circuit forming method of claim 5, wherein the step (b) is conducted after the step (a).

7. The electromagnetic wave shielding wiring circuit forming method of claim 5 or 6, wherein the coating or printing is conducted by an inkjetting or screen printing method, respectively.

8. An electromagnetic wave shielding sheet comprising:
a wiring circuit formed by the electromagnetic wave shielding wiring circuit forming method of any one of claims 1 to 7; and
protective films provided on both upper and lower surfaces of the wiring circuit, respectively.
